(19) United States
(12) Patent Application Publication
(10) Pub. No.: US 2020/0412349 A1
(43) Pub. Date: Dec. 31, 2020

(54) METHOD AND CIRCUIT USED TO OBTAIN TIME LIMITS FOR OBTAINING CLOCK EDGE ADJUSTMENT VALUE TO ADJUST CLOCK EDGE OF CLOCK SIGNAL ACCORDINGLY

(71) Applicant: Sunplus Technology Co., Ltd., Hsinchu (TW)

(72) Inventors: XIAOHONG Du, Chengdu (CN); KUN ZHANG, Chengdu (CN)

(21) Appl. No.: 16/884,052

(22) Filed: May 27, 2020

(30) Foreign Application Priority Data
Jun. 27, 2019 (CN) 201910564980.0

(51) Int. Cl. H03K 5/133; H03K 3/037; G06F 1/08

(52) U.S. Cl. CPC H03K 5/133; G06F 1/08; H03K 3/037

(57) ABSTRACT

A method for adjusting a clock edge of a clock signal includes a transmission terminal sending a first set of transmission packets to a reception terminal; performing a check operation to check at least whether the first set of transmission packets is correctly received; obtaining a first time limit and a second time limit according to a result of the check operation; obtaining a clock edge adjustment value according to the first time limit and the second time limit; and adjusting the clock edge according to the clock edge adjustment value.

### BACKGROUND OF THE INVENTION

### 1. Field of the Invention

The disclosure is related to a method and a circuit used for adjusting a clock edge of a clock signal, and more particularly, a method and a circuit used to obtain time limits for obtaining a clock edge adjustment value to adjust a clock edge of a clock signal accordingly.

### 2. Description of the Prior Art

When two chips formed with different manufacture processes and operation speeds are connected with wire bonds to generate a system-in-chip (SiP), there can be a high-speed digital interface between the two chips. If the two chips are defined as a transmission terminal and a reception terminal according to the direction of the signal, the digital interface can be located between the transmission terminal and the reception terminal. The data transmitted through the digital interface can include a data signal and a clock signal. Because the process, voltage and temperature (a.k.a. PVT) and other issues can affect the signals, when the clock signal is transmitted from the transmission terminal to the reception terminal and then transmitted through a clock tree circuit, the clock signal received by the digital circuit of the reception terminal can be different from the expected clock signal with an unexpected phase difference. The digital circuit of the reception terminal will hence fail to correctly sample and receive data, and fail to correctly operate.

### SUMMARY OF THE INVENTION

An embodiment provides a method for adjusting a clock edge of a clock signal. The method includes a transmission terminal sending a first set of transmission packets to a reception terminal; performing a check operation to check at least whether the first set of transmission packets is correctly received; obtaining a first time limit and a second time limit according to a result of the check operation; obtaining a clock edge adjustment value according to the first time limit and the second time limit; and adjusting the clock edge according to the clock edge adjustment value.

Another embodiment provides a circuit for adjusting a clock edge of a clock signal. The circuit includes an inverter, a first multiplexer, a delay unit, a second multiplexer and a control unit. The inverter is used to invert a clock signal to generate an inverted clock signal and includes an input terminal used to receive the clock signal, and an output terminal used to output the inverted clock signal. The first multiplexer includes a first terminal used to receive the clock signal, a second terminal coupled to the output terminal of the inverter, a selection terminal used to receive a first selection signal, and an output terminal used to output the clock signal or the inverted clock signal according to the first selection signal. The delay unit includes an input terminal coupled to the output terminal of the first multiplexer, a first output terminal used to output a first delayed clock signal, a second output terminal used to output a second delayed clock signal, and a third output terminal used to output a third delayed clock signal where the first delayed clock signal is generated by delaying a stored clock signal by a predetermined value and the stored clock signal is used by a flip-flop to correctly receive data, the second delayed clock signal is generated by delaying the first delayed clock signal by half of the predetermined value, and the third delayed clock signal is generated by delaying the stored clock signal by half of the predetermined value. The second multiplexer includes a first terminal coupled to the output terminal of the first multiplexer, a second terminal coupled to the first output terminal of the delay unit, a third terminal coupled to the second output terminal of the delay unit, a fourth terminal coupled to the third output terminal of the delay unit, a selection terminal used to receive a second selection signal, and an output terminal coupled to a clock terminal of the flip-flop. The control unit includes an input terminal used to receive an activation signal, a first output terminal coupled to the selection terminal of the first multiplexer and used to output the first selection signal, and a second output terminal coupled to the selection terminal of the second multiplexer and used to output the second selection signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a circuit of a transmission terminal and a reception terminal according to an embodiment.

FIG. 2 illustrates waveform of the signals transmitted in FIG. 1.

FIG. 3 illustrates that the signals shown in FIG. 2 are adjusted and expressed in one period of the clock signal.

FIG. 4 illustrates a method for adjusting a clock edge of a clock signal according to an embodiment.

FIG. 5 and FIG. 6 illustrate detailed flowcharts of FIG. 4 according to an embodiment.

FIG. 7 to FIG. 10 illustrate that the first time limit and the second time limit are obtained using the steps shown in FIG. 4 to FIG. 6 in different examples.

FIG. 11 illustrates a state diagram of sending packets between the transmission terminal and the reception terminal according to the embodiment of FIG. 1.

FIG. 12 illustrates a circuit capable of adjusting the clock edge of the clock signal according to an embodiment.

### DETAILED DESCRIPTION

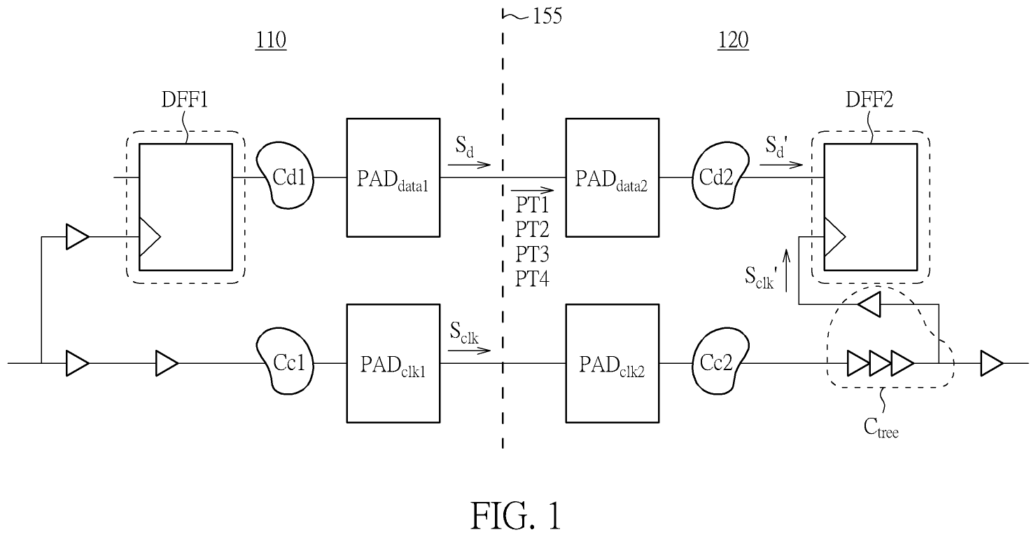

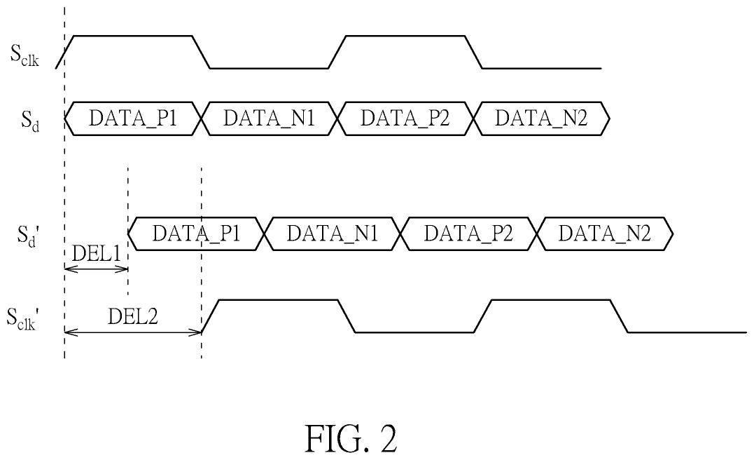

FIG. 1 illustrates a circuit of a transmission terminal 110 and a reception terminal 120 according to an embodiment. FIG. 2 illustrates signals of the circuit of FIG. 1. As shown in FIG. 1, the transmission terminal 110 and the reception terminal 120 may be (but not limited to) two chips. In FIG. 1, the data transmitted by a flip-flop DFF1 may be sent through a circuit Cd1, and a clock signal may be sent through a circuit Cc1. A data signal S_{d} transmitted by the flip-flop DFF1 of the transmission terminal 110 may be transmitted through a data pad PAD_{data1} to a data pad PAD_{data2}. The data signal S_{d} may include data DATA_P1, DATA_N1, DATA_P2 and DATA_N2, etc. A clock signal S_{clk} transmitted by the transmission terminal 110 may be transmitted through a clock pad PAD_{clk1} to a clock pad PAD_{cclk2}. An interface 155 between the transmission terminal 110 and the reception terminal 120 may be a digital interface. As shown in FIG. 1, because the data signal S_{d} passes through a circuit Cd2 of the reception terminal 120 before reaching a data terminal of a flip-flop DFF2, and the clock signal S_{clk} passes through a circuit Cc2 and a clock tree circuit Cₜᵣₑₑ of the reception terminal 120 before reaching a clock terminal of the flip-flop DFF2, phases of the signals may change when the signals reach the flip-flop DFF2. The data terminal of the flip-flop DFF2 may receive a data signal S_{d}′, and the clock terminal of the flip-flop DFF2 may receive a clock signal S_{clk}′.

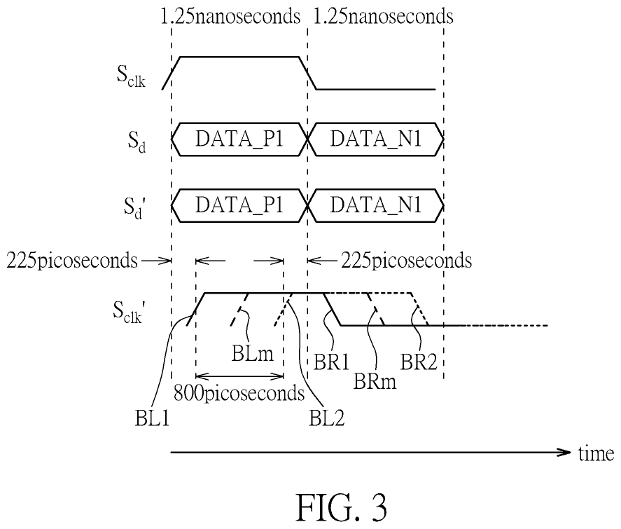

The phases of the data signal S_{d}, the clock signal S_{clk}, the data signal S_{d}′, the clock signal S_{clk}′ may be shown as FIG. 2. The signal edges of the data signal S_{d} and the clock signal S_{clk} may be aligned. However, because a phase of a signal may change when reaching the flip-flop DFF2, there may be a latency DEL1 between the data signal Sd′ and the data signal Sd, and there may be a latency DEL2 between the clock signal Sclk′ and the clock signal S_{clk}. FIG. 3 illustrates that the signals shown in FIG. 2 are adjusted and expressed in one period of the clock signal S_{clk}. As shown in FIG. 3, regarding the allowable clock edges of the clock signal S_{clk}′, for the flip-flop DFF2 to correctly receive the data signal S_{d}′, the leftmost edges may be the clock edge BL1 (e.g., a rising edge) and the clock edge BR1 (e.g., a falling edge), and the rightmost edges may be the clock edge BL2 (e.g., a rising edge) and the clock edge BR2 (e.g., a falling edge). In this example, the time axis is from left to right. If the clock signal S_{clk}′ has a left edge at the left side of the clock edge BL1 and a right edge at the left side of the clock edge BR1, a setup time violation may occur at the flip-flop DFF2. If the clock signal S_{clk}′ has a left edge at the right side of the clock edge BL2 and a right edge at the right side of the clock edge BR2, a hold time violation may occur at the flip-flop DFF2.

In other words, the left edge of the clock signal S_{clk}′ should be located within a window between the clock edges BL1 and BL2, and the right edge of the clock signal S_{clk}′ should be located within a window between the clock edges BR1 and BR2. Hence, as shown in FIG. 3, the left edge of the clock signal S_{clk}′ should have a left limit and a right limit that are BL1 and BL2 respectively. The right edge of the clock signal S_{clk}′ should have a left limit and a right limit that are BR1 and BR2 respectively.

Hence, the two clock edges of the clock signal S_{clk}′ may be a clock edge BLm (e.g., a rising edge) and a clock edge BRm (e.g., a falling edge). The clock edge BLm may be at the middle position between the clock edges BL1 and BL2. The clock edge BRm may be at the middle position between the clock edges BR1 and BR2. When the two clock edges of the clock signal S_{clk}′ are the clock edges BLm and BRm, the clock signal S_{clk}′ may withstand a largest error. In other words, even if the phase of the clock signal S_{clk}′ is shifted due to process, temperature, voltage or other factors, the probability of that the flip-flop DFF2 fails to sample data is relatively low.

In an example of FIG. 3, for the clock signals S_{clk} and S_{clk}′, a period may be 2.5 nanoseconds (ns) and a semi-period may be 1.25 ns. For the flip-flop DFF2, the setup time may be 225 picoseconds (ps), and the hold time may be 225 ps. Hence, the window between the clock edges BL1 and BL2 may be 800 ps. The above numbers are merely examples instead of limiting the scope of embodiments.

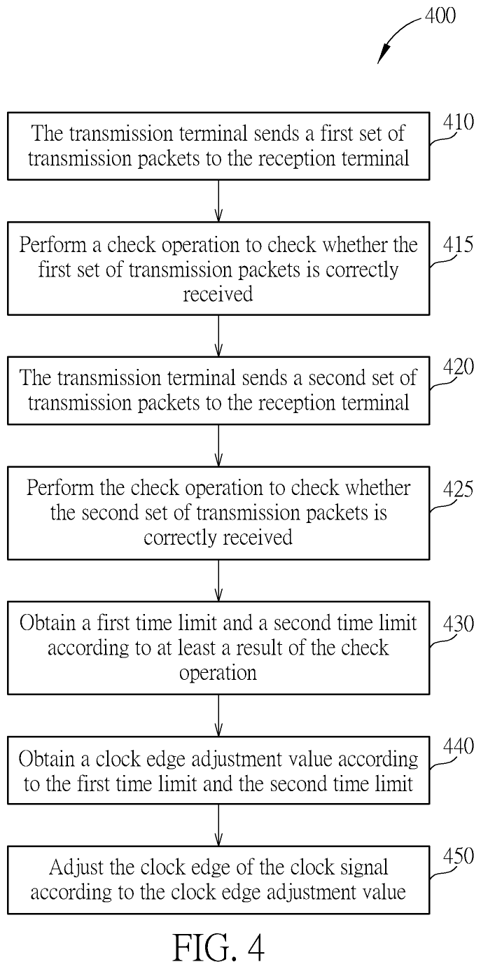

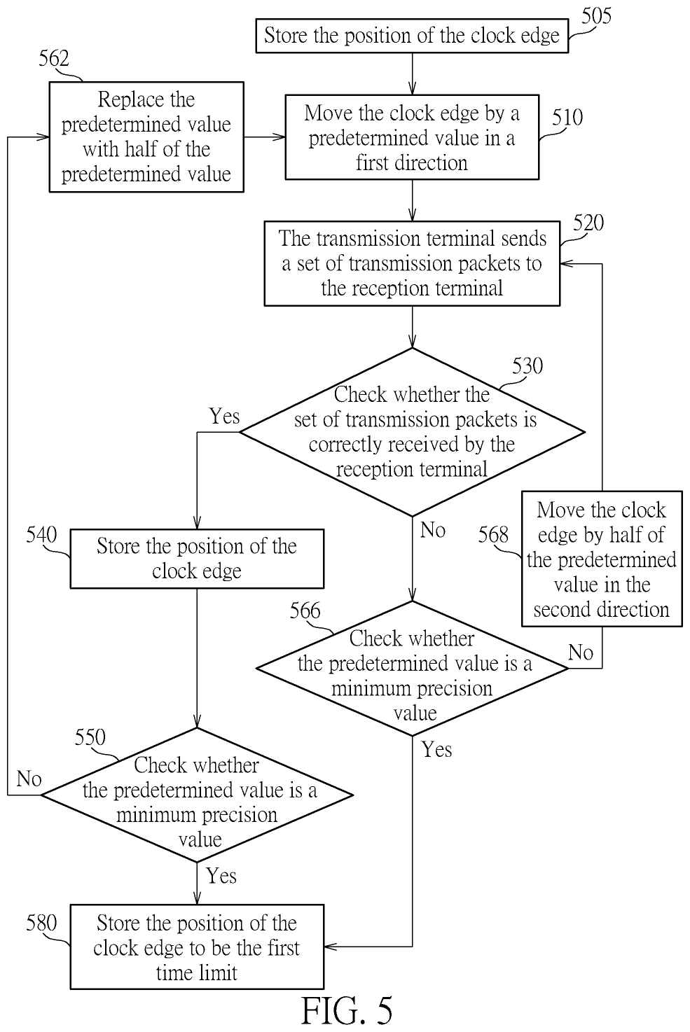

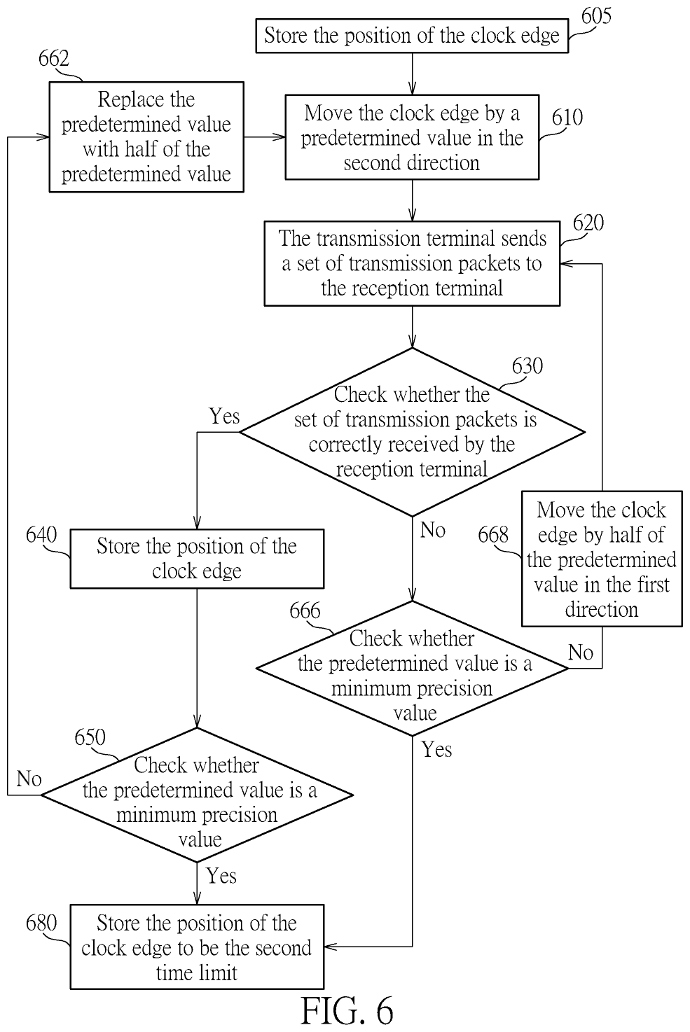

As above, if the window, the left limit and the right limit corresponding to the clock edges of the clock signal S_{clk}′ are obtained on the time axis, and the clock S_{clk}′ is adjusted accordingly, the probability of incorrect sampling may be reduced. The tolerance of the whole circuit to the error of the clock signal may be improved. Hence, a method is provided to obtain the foresaid left limit and right limit. FIG. 4 illustrates a method 400 for adjusting a clock edge Bs of the clock signal S_{clk}′ according to an embodiment. FIG. 5 and FIG. 6 illustrate detailed flowcharts of FIG. 4 according to an embodiment.

Taking the circuit of FIG. 1 as an example, the method 400 may include the following steps.

Step 410: the transmission terminal 110 sends a first set of transmission packets PT1 to the reception terminal 120;

Step 415: perform a check operation to check whether the first set of transmission packets PT1 is correctly received;

Step 420: the transmission terminal 110 sends a second set of transmission packets PT2 to the reception terminal 120;

Step 425: perform the check operation to check whether the second set of transmission packets PT2 is correctly received;

Step 430: obtain a first time limit BR and a second time limit BL according to at least a result of the check operation;

Step 440: obtain a clock edge adjustment value Ev according to the first time limit BR and the second time limit BL; and

Step 450: adjust the clock edge Bs of the clock S_{clk}′ according to the clock edge adjustment value Ev.

In the examples of the present disclosure, the first time limit BR described in FIG. 4 may be (but not limited to) a right limit, and the second time limit BL described in FIG. 4 may be (but not limited to) a left limit. The time goes from left to right on the time axis. The setting is merely used as an example instead of limiting the scope of embodiments. In addition, for example, if the flip-flop DFF2 samples data at the clock edge Bs of the clock signal S_{clk}′, the obtained first time limit BR and the second time limit BL may be used to adjust the clock edge Bs.

FIG. 5 illustrates a flowchart of obtaining the first time limit BR in Step 410 to Step 430 of FIG. 4 according to an embodiment. The first time limit BR may be obtained using the following steps.

Step 505: store the position of the clock edge Bs;

Step 510: move the clock edge Bs by a predetermined value X in a first direction DR to adjust the clock signal S_{clk}′;

Step 520: the transmission terminal 110 sends a set of transmission packets PT to the reception terminal 120;

Step 530: perform the check operation to check whether the set of transmission packets PT is correctly received by the reception terminal 120; if so, go to Step 540; else go to Step 566;

Step 540: store the position of the clock edge Bs;

Step 550: check whether the predetermined value X is a minimum precision value; if so, go to Step 580; else go to Step 562;

Step 562: replace the predetermined value X with half of the predetermined value X (i.e. X/2); go to Step 510;

Step 566: check whether the predetermined value X is a minimum precision value; if so, go to Step 580; else go to Step 568;

Step 568: move the clock edge Bs by half of the predetermined value X (i.e. X/2) in the second direction DL to adjust the clock signal S_{clk}′ go to Step 520;

Step 580: store the position of the clock edge Bs to be the first time limit BR.

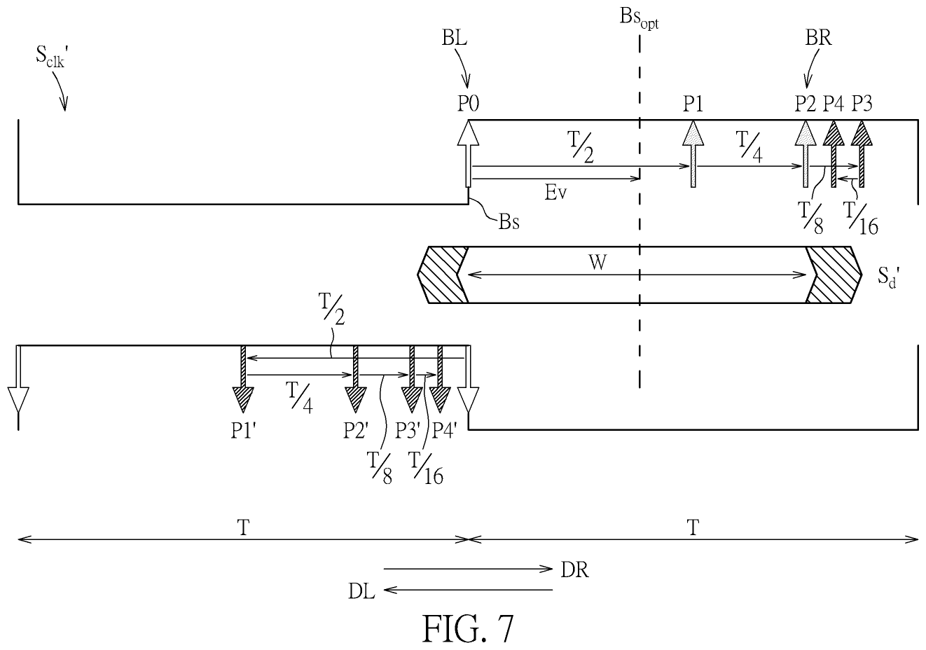

In the flow, if the transmission packets PT are sent for n times, the transmission packets PT sent in the (n−1)ₜₕ time may be the abovementioned first set of transmission packets PT1, and the transmission packets PT sent in the nₜₕ time may be the abovementioned second set of transmission packets PT2 where n is a positive integer larger than 1. In the example of FIG. 7 to FIG. 10, n is 4; however, this is merely an example instead of limiting the scope of embodiments.

FIG. 6 illustrates a flowchart of obtaining the second time limit BL in Step 410 to Step 430 of FIG. 4 according to an embodiment. The second time limit BL may be obtained using the following steps.

Step 605: store the position of the clock edge Bs;

Step 610: move the clock edge Bs by a predetermined value X in the second direction DL to adjust the clock signal S_{clk}′;

Step 620: the transmission terminal 110 sends a set of transmission packets PT to the reception terminal 120;

Step 630: perform the check operation to check whether the set of transmission packets PT is correctly received by the reception terminal 120; if so, go to Step 640; else go to Step 666;

Step 640: store the position of the clock edge Bs;

Step 650: check whether the predetermined value X is a minimum precision value; if so, go to Step 680; else go to Step 662;

Step 662: replace the predetermined value X with half of the predetermined value X (i.e. X/2); go to Step 610;

Step 666: check whether the predetermined value X is a minimum precision value; if so, go to Step 680; else go to Step 668;

Step 668: move the clock edge Bs by half of the predetermined value X (i.e. X/2) in the first direction DR to adjust the clock signal S_{clk}′ go to Step 620;

Step 680: store the position of the clock edge Bs to be the second time limit BL.

In the flow, if the transmission packets PT are sent fork times, the transmission packets PT sent in the (k−1)ₜₕ time may be the abovementioned first set of transmission packets PT1, and the transmission packets PT sent in the kₜₕ time may be the abovementioned second set of transmission packets PT2 where k is a positive integer larger than 1. In the example of FIG. 7 to FIG. 10, k is 4; however, this is merely an example instead of limiting the scope of embodiments. The steps in FIG. 6 are used to obtain the second time limit BL of the second direction DL (e.g., the left direction of FIG. 7 to FIG. 10), and in Step 605, the signal phase related to the clock edge Bs may be optionally inverted according to that the flip-flop DFF2 is triggered by a rising edge or a falling edge when sampling the data signal S_{d}′.

The packets mentioned in FIG. 4 to FIG 6 may be corresponding to the data signal S_{d}′ received by the flip-flop DFF2. FIG. 7 to FIG. 10 illustrate the first time limit BR and the second time limit BL are obtained using the steps of FIG. 4 to FIG. 6 in different embodiments. In FIG. 7 to FIG. 10, the clock signal S_{clk}′ may have a period 2T.

In FIG. 7, an initial clock edge Bs may be at the leftmost side of a window W of the data signal S_{d}′. If the clock edge Bs is within the window W, the clock signal S_{clk}′ may be correctly used by the flip-flop to receive and sample the data signal S_{d}′ without a setup time violation and a hold time violation. Hence, in the case of FIG. 7, the clock edge Bs is allowed to be moved along the first direction DR (e.g., the right direction) instead of the second direction DL (e.g., the left direction). To obtain the first time limit BR (e.g., a right limit) of the clock edge Bs, the following operations may be performed according to FIG.5.

First, as Step 505, an initial position PO of the clock edge Bs may be stored. Then, as Step 510, the clock edge Bs is moved from the position PO to a first update position P1 by a predetermined value X where X=T/2.

When the clock edge Bs is at the first update position P1, the transmission terminal 110 may send the first set of transmission packets PT1 to the reception terminal 120 as described in Step 520. As described in Step 530, it may be checked whether the first set of transmission packets PT1 is correctly received by the reception terminal 120. As shown in FIG. 7, because the clock edge Bs is still within the window W when the clock edge Bs is at the first update position P1, the reception terminal 120 may correctly receive and sample the first set of transmission packets PT1. Hence, as described in Step 540, the position of the clock edge Bs at the time (i.e. the first update position P1) may be stored. Then, as described in Step 550, it may be checked whether the predetermined value X at the time (i.e. T/2) is the minimum precision value. In this example, the minimum precision value may be T/16. Hence, the predetermined value X at the time (i.e. T/2) is not yet the minimum precision value, half of the predetermined value X (i.e. X/2 and T/4) may be used to replace the predetermined value X (i.e. T/2). Then, Step 520 may be performed.

At this time, the clock edge Bs may be moved from the first update position P1 to the second update position P2, and the transmission terminal 110 may send a second set of transmission packets PT2 to the reception terminal 120. As described in Step 530, it may be checked whether the second set of transmission packets PT2 is correctly received by the reception terminal 120.

Because the clock edge Bs is still within the window W when the clock edge Bs is at the second update position P2, the reception terminal 120 may correctly receive and sample the second set of transmission packets PT2. In addition, the predetermined value X at the time (i.e. T/4) is not yet the minimum precision value (i.e. T/16), so the position of the clock edge Bs at the time (i.e. the second update position P2) can be stored as described in Step 540. Moreover, as described in Steps 550, 562 and 510, the clock edge Bs may be moved in the first direction DR (e.g. the right direction) by T/8 to the third update position P3.

When the clock edge Bs is at the third update position P3, the transmission terminal 110 may send a third set of transmission packets PT3 to the reception terminal 120. However, as shown in FIG. 7, the third update position P3 is not within the window W, so the reception terminal 120 may not correctly receive the third set of transmission packets PT3. Hence, the position of the clock edge Bs at the time may not be stored. In addition, the predetermined value T/8 at the time is not the minimum precision value, so the clock edge Bs may be moved in the second direction DL (e.g., the left direction) by half of the predetermined value (i.e. T/16 in this example) to adjust the clock signal S_{clk}′ as described in Steps 530, 566 and 568. Hence, the clock edge Bs may be moved from the third update position P3 to the fourth update position P4.

Then, as described in Step 520, the transmission terminal 110 may send a fourth set of transmission packets PT4. As described in Step 530, it may be checked whether the fourth set of transmission packets PT4 is correctly received by the reception terminal 120. As shown in FIG.7, when the clock edge Bs is at the fourth update position P4, the clock edge Bs may not be within the window W. Hence, when the clock edge Bs is at the fourth update position P4, in Step 530, the fourth set of transmission packets PT4 may fail to be correctly received by the reception terminal 120. Step 566 may be performed to not store the position of the clock edge Bs. Further, because the predetermined value X at the time has been updated three times to become T/16, the predetermined value X already has the minimum precision value. The result of Step 566 may be “yes”, and Step 580 may be performed.

As above, when the clock edge Bs is at the second update position P2, the reception terminal 120 may correctly receive a set of packets, so the second update position P2 may be stored. However, when the clock edge Bs is at the third update position P3 and the fourth update position P4, the reception terminal 120 may fail to correctly receive a set of packets, so the update positions P3 and P4 may not be stored. Hence, in Step 580, the last stored position of the clock edge Bs may be the second update position P2. The second update position P2 may hence be used to be the first time limit BR.

In other words, according to the method shown in FIG.5, in order to obtain the first time limit (e.g., a right limit) of the clock edge Bs, the clock edge Bs may be moved to the right by the predetermined value X, and a set of packets may be sent. When the set of packets is correctly received and the predetermined value X is not the minimum precision value, the clock edge Bs may be further moved to the right by X/2. In another scenario, when the set of packets fails to be correctly received and the predetermined value X is not the minimum precision value, the clock edge Bs may be moved back to the left by X/2. In the example above, the predetermined value X may be T/2, T/4, T/8 and T/16 sequentially in different steps. When the predetermined value X is T/16 (i.e. the minimum precision value), the method is terminated.

Steps shown in FIG.6 may be used to obtain the second time limit BL (e.g., the left limit) of the clock edge Bs. FIG 6 may be similar to FIG. 5, but the directions described in FIG. 6 are different from that in FIG. 5. As mentioned above, the clock edge Bs may be a rising edge or a falling edge selectively, and the phase of the clock signal may be optionally inverted.

According to FIG. 6, in the example of FIG. 7, the initial position PO of the clock edge Bs may be stored. Then, the clock edge Bs may be moved from the initial position PO by the predetermined value X (i.e. T/2) to the first update position P1′. Because the clock edge Bs is not within the window W, the reception terminal 120 may fail to correctly receive the packets sent by the transmission terminal 110, and the position of the clock edge Bs (i.e. position P1′) may not be stored.

Because the packets sent by the transmission terminal 110 are not correctly received, the clock edge Bs may be moved by the updated predetermined value X (i.e. T/4) from the first update position P1′ to the second update position P2′. Because the clock edge Bs is still not within the window W, the reception terminal 120 may fail to correctly receive the packets sent by the transmission terminal 110, and the position of the clock edge Bs (i.e. the position P2′) may not be stored.

Because the packets sent by the transmission terminal 110 are not correctly received, the clock edge Bs may be moved by the updated predetermined value X (i.e. T/8) from the second update position P2′ to the third update position P3′. Because the clock edge Bs is still not within the window W, the reception terminal 120 may still fail to correctly receive the packets sent by the transmission terminal 110, and the position of the clock edge Bs (i.e. the position P3′) may not be stored.

Because the packets sent by the transmission terminal 110 are not correctly received, the clock edge Bs may be moved by the updated predetermined value X (i.e. T/16) from the third update position P3′ to the fourth update position P4′. Because the clock edge Bs is still not within the window W, the reception terminal 120 may still fail to correctly receive the packets sent by the transmission terminal 110, and the position of the clock edge Bs (i.e. the position P3′) may not be stored. Because the predetermined value X (i.e. T/16) has the minimum precision value, the last stored position of the clock edge Bs may be used to be the second time limit BL (e.g., the left limit). In the example of FIG. 7, the second time limit BL may be the initial position P0.

As described in Steps 440 and 450, the clock edge adjustment value Ev may be obtained according to the first time limit BR and the second time limit BL, and the clock edge Bs may be adjusted according to the clock edge adjustment value Ev. In the example of FIG. 7, after performing the steps of FIG. 5 and FIG. 6, the first time limit BR and the second time limit BL of the clock edge Bs may be the update position P2 and the initial position P0. As described in FIG. 3, an optimized position of the clock edge Bs may be (but not limited to) at the middle position between the first time limit BR and the second time limit BL. Hence, as shown in FIG. 7, the clock edge adjustment value Ev may be obtained for adjusting the clock edge Bs to an improved clock edge position Bsₒₚₜ. The improved clock edge position Bsₒₚₜ may be the middle position between the time limits BR and BL. The clock edge adjustment value Ev in FIG. 7 may be expressed as an equation (eq-1).

Ev=(BR+BL)÷2=((T/2+T/4)+0)÷2=3T/8 (eq-1).

After moving the clock edge Bs to the improved clock edge position Bsₒₚₜ, the clock edge Bs may be substantially at the middle position of the window W. The influence of variances of the clock signal caused by unexpected factors may be reduced, and the unexpected factors may relate to the manufacture process, voltage and temperature.

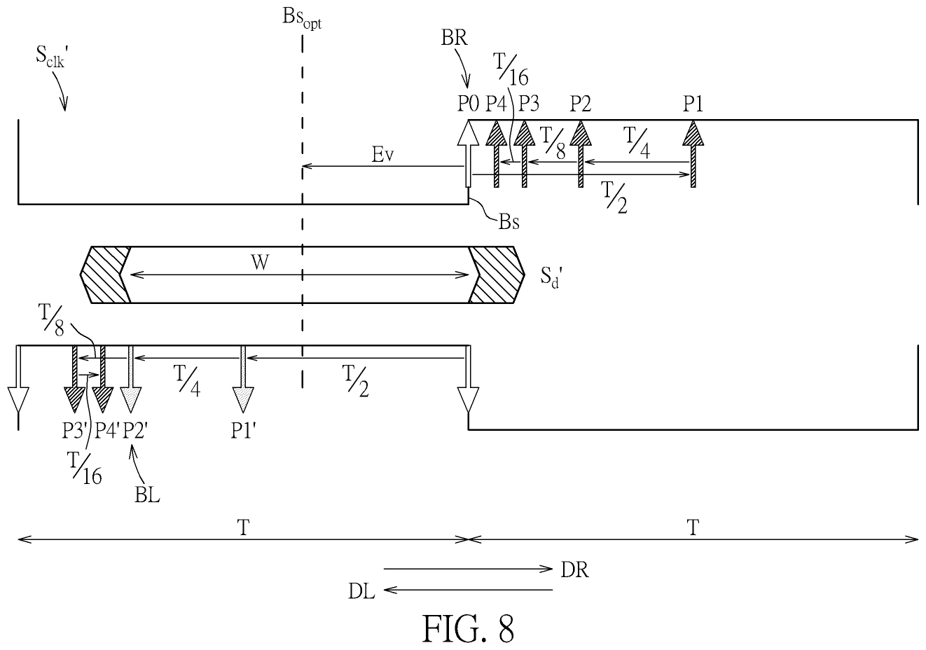

In the examples of FIG. 8 to FIG. 10, the steps for obtaining the first time limit BR and the second time limit BL may be similar to that of FIG.7 and will be described below. For example, the first direction DR and the second direction DL along the time axis may be the right direction and the left direction.

In the example of FIG. 8, the clock edge Bs may be moved right from the initial position PO to the first update position P1 by the predetermined value X (i.e. T/2). Because the reception terminal 120 may fail to correctly receive the packets sent by the transmission terminal 110, the clock edge Bs may be moved left from the first update position P1 to the second update position P2 by the updated predetermined value X (i.e. T/4). Because the reception terminal 120 may still fail to correctly receive the packets sent by the transmission terminal 110, the clock edge Bs may be moved left from the second update position P2 to the third update position P3 by the updated predetermined value X (i.e. T/8). Because the reception terminal 120 may still fail to correctly receive the packets sent by the transmission terminal 110, the clock edge Bs may be moved left from the third update position P3 to the fourth update position P4 by the updated predetermined value X (i.e. T/16). At the time, the predetermined value X (i.e. T/16) has the minimum precision value, so the first time limit BR may be the last stored initial position P0.

Regarding the second time limit BL in FIG. 8, the phase of the clock signal S_{clk}′ may be optionally inverted to adjust the clock edge Bs. The clock edge Bs may be moved left from the initial position PO to the first update position P1′ by the predetermined value X (i.e. T/2). Because the first update position P1′ is within the window W, the reception terminal 120 may correctly receive the packets sent by the transmission terminal 110, and the first update position P1′ may be stored. The clock edge Bs may be further moved left from the first update position P1′ to the second update position P2′ by the updated predetermined value X (i.e. T/4). Because the second update position P2′ is still within the window W, the reception terminal 120 may correctly receive the packets sent by the transmission terminal 110, and the second update position P2′ may be stored. The clock edge Bs may be further moved left from the second update position P2′ to the third update position P3′ by the updated predetermined value X (i.e. T/8). Because the third update position P3′ is not within the window W, the reception terminal 120 may fail to correctly receive the packets sent by the transmission terminal 110, and the clock edge Bs may be moved right from the third update position P3′ to the fourth update position P4′ by the updated predetermined value X (i.e. T/16). At the time, the predetermined value X (i.e. T/16) has the minimum precision value, so the first time limit BL may be the last stored position P2′.

The clock edge adjustment value Ev in FIG.8 may be expressed as an equation (eq-2).

Ev=(BR+BL)÷2=(0−(T/2+T/4))÷2=−3T/8 (eq-2).

In the equation, the minus sign may be corresponding to the second direction DL (e.g., the left direction). Hence, the clock edge Bs may be moved left by 3T/8 to the improved clock edge position Bsₒₚₜ.

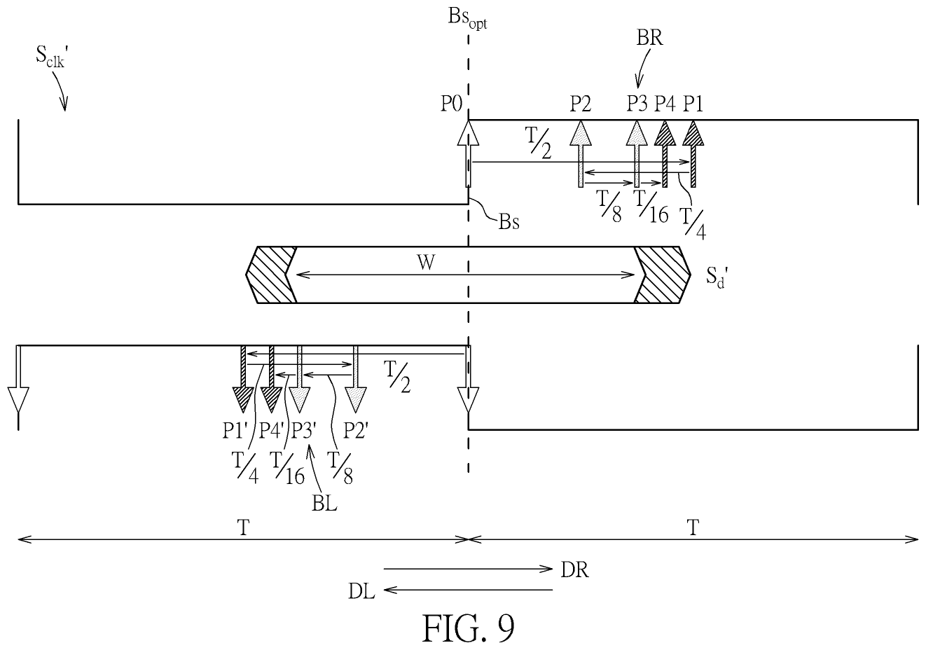

Regarding the first time limit BR in FIG. 9, according to the method of FIG. 5, the clock edge Bs may be moved from the initial position P0 to the first update position P1, the second update position P2, the third update position P3 and the fourth update position P4 sequentially. When the clock edge Bs is at the positions P1 and P4, the reception terminal may fail to correctly receive the packets, so the positions P1 and P4 may not be stored. When the clock edge Bs is at the positions P2 and P3, the reception terminal may correctly receive the packets, so the positions P2 and P3 may be stored. Hence, the last stored position P3 may be used as the first time limit BR. Regarding the second time limit BL in FIG. 9, the phase of the clock signal may be optionally inverted to adjust the clock edge Bs. According to the method of FIG. 6, the clock edge Bs may be moved from the initial position PO to the first update position P1′, the second update position P2′, the third update position P3′ and the fourth update position P4′ sequentially. When the clock edge Bs is at the positions P1′ and P4′, the reception terminal may fail to correctly receive the packets, so the positions P1′ and P4′ may not be stored. When the clock edge Bs is at the positions P2′ and P3′, the reception terminal may correctly receive the packets, so the positions P2′ and P3′ may be stored. Hence, the last stored position P3′ may be used as the second time limit BL.

The clock edge adjustment value Ev in FIG. 9 may be expressed as an equation (eq-3).

Ev=(BR+BL)÷2=((T/2−T/4+T/8)−(T/2−T/4+T/8))÷2=0T (eq-3).

Hence, the clock edge Bs may be moved by OT to obtain the improved clock edge position Bsₒₚₜ. In other words, the clock edge Bs may not be moved, and the improved clock edge position Bsₒₚₜ may be the initial position P0 in FIG. 9.

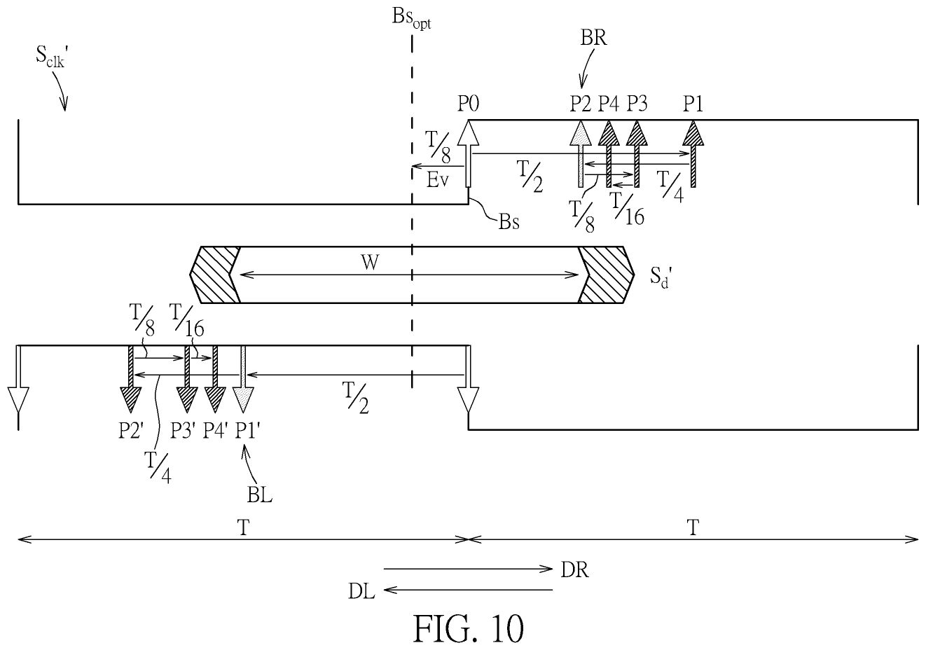

Regarding the first time limit BR in FIG. 10, according to the method of FIG. 5, the clock edge Bs may be moved from the initial position P0 to the first update position P1, the second update position P2, the third update position P3 and the fourth update position P4 sequentially. When the clock edge Bs is at the positions P1, P3 and P4, the reception terminal may fail to correctly receive the packets, so the positions P1, P3 and P4 may not be stored. When the clock edge Bs is at the position P2, the reception terminal may correctly receive the packets, so the position P2 may be stored. Hence, the last stored position P2 may be used as the first time limit BR. Regarding the second time limit BL in FIG. 10, the phase of the clock signal may be optionally inverted to adjust the clock edge Bs. According to the method of FIG. 6, the clock edge Bs may be moved from the initial position P0 to the first update position P1′, the second update position P2′, the third update position P3′ and the fourth update position P4′ sequentially. When the clock edge Bs is at the positions P2′, P3′ and P4′, the reception terminal may fail to correctly receive the packets, so the positions P2′, P3′ and P4′ may not be stored. When the clock edge Bs is at the position P1′, the reception terminal may correctly receive the packets, so the position P1′ may be stored. Hence, the last stored position P1′ may be used as the second time limit BL.

The clock edge adjustment value Ev in FIG. 10 may be expressed as an equation (eq-4).

Ev=(BR+BL)÷2=((T/2−T/4)−T/2)÷2=−T/8 (eq-4).

Hence, the clock edge Bs may be moved to the improved clock edge position Bsₒₚₜ by T/8 in the second direction DL.

As described with the examples shown in FIG. 7 to FIG. 10, clock edge adjustment value Ev may be obtained under different conditions, and be used to adjust the clock edge Bs to the improved clock edge position Bsₒₚₜ.

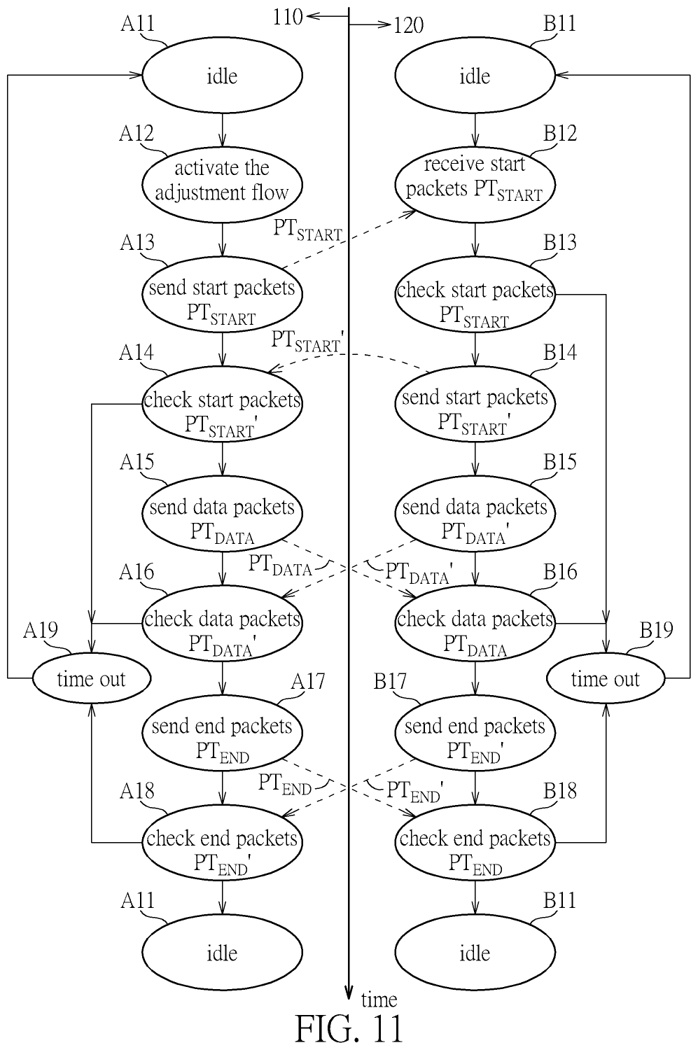

FIG.11 illustrates a state diagram of sending packets between the transmission terminal 110 and the reception terminal 120 according to the embodiment of FIG. 1. FIG. 11 may show a flow of sending and checking packets when the clock edge Bs is adjusted once. In FIG. 11, the states A11 to A19 may be corresponding to the transmission terminal 110, and the states B11 to B19 may be corresponding to the reception terminal 120. In the states A11 and B11, the transmission terminal 110 and the reception terminal 120 may be at the idle state.

When a predetermined condition is reached, the state A12 may be entered to activate the adjustment flow for adjusting the clock edge Bs. The predetermined condition may include that an event monitor has observed a predetermined event such as change(s) related to process, voltage and/or temperature.

After the adjustment flow has been activated, the transmission terminal 110 may send a set of start packets PT_{START}. The reception terminal 120 may enter the states B12 and B13 to receive and check the set of start packets PT_{START}. If the reception terminal 120 fails to obtain the correct result of checking the set of start packets PT_{START} after a predetermined time interval has elapsed in the state B13, the reception terminal 120 can enter a time out state B19, and enter the idle state B11. The reception terminal 120 may also optionally enter the state B14 to send a set of start packets PT_{START}′, and the transmission terminal 110 may check the set of start packets PT_{START}′ in the state A14. If the transmission terminal 110 fails to obtain the correct result of checking the set of start packets PT_{START}′ after a predetermined time interval has elapsed in the state A14, the transmission terminal 110 can enter a time out state A19, and enter the idle state A11.

If the transmission terminal 110 can obtain the correct result of checking the set of start packets PT_{START}′ in the state A14, the transmission terminal 110 may enter the state A15 to send a set of data packets PT_{DATA} to the reception terminal 120, and the reception terminal 120 may check the set of data packets PT_{DATA} in the state B16. If the reception terminal 120 fails to obtain the correct result of checking the set of data packets PT_{DATA} after a predetermined time interval has elapsed in the state B16, the reception terminal 120 can enter the time out state B19, and enter the idle state B11. The reception terminal 120 may optionally enter the state B15 to send a set of data packets PT_{DATA}′ to the transmission terminal 110, and the transmission terminal 110 may check the set of data packets PT_{DATA}′ in the state A16. If the transmission terminal 110 fails to obtain the correct result of checking the set of data packets PT_{DATA}′ after a predetermined time interval has elapsed in the state A16, the transmission terminal 110 can enter the time out state A19, and enter the idle state A11.

If the transmission terminal 110 can obtain the correct result of checking the set of start packets PT_{DATA}′ in the state A16, the transmission terminal 110 may enter the state A17 to send a set of end packets PT_{END} to the reception terminal 120, and the reception terminal 120 may check the set of end packets PT_{END} in the state B18. If the reception terminal 120 fails to obtain the correct result of checking the set of end packets PT_{END} after a predetermined time interval has elapsed in the state B18, the reception terminal 120 can enter the time out state B19, and enter the idle state B11. The reception terminal 120 may optionally enter the state B17 to send a set of end packets PT_{END}′ to the transmission terminal 110, and the transmission terminal 110 may check the set of end packets PT_{END}′ in the state A18. If the transmission terminal 110 fails to obtain the correct result of checking the set of data packets PT_{END}′ after a predetermined time interval has elapsed in the state A18, the transmission terminal 110 can enter the time out state A19, and enter the idle state A11.

The set of packets PT and the first set of transmission packets PT1 to the fourth set of transmission packets PT4 described above may include the set of start packets PT_{START}, the set of data packets PT_{DATA} and the set of end packets PT_{END} shown in FIG. 11. As shown in FIG. 11, the reception terminal 120 may send back a set of return packets to the transmission terminal 110, where the set of return packets may include the set of start packets PT_{START}′, the set of data packets PT_{DATA}′ and the set of end packets PT_{END}′. In other words, in order to confirm the flip-flop DFF2 of the reception terminal 120 may correctly receive packets and sample data, the transmission terminal 110 may send packets to the reception terminal 120, or the transmission terminal 110 and the reception terminal 120 may send packets to one another to perform a handshake process. The steps of sending and checking packets after moving the clock edge Bs described above (e.g., Steps 410 to 425 of FIG.4, Steps 520 and 530 of FIG. 5 and Steps 620 and 630 of FIG. 6) may be performed according to the flow of FIG. 11.

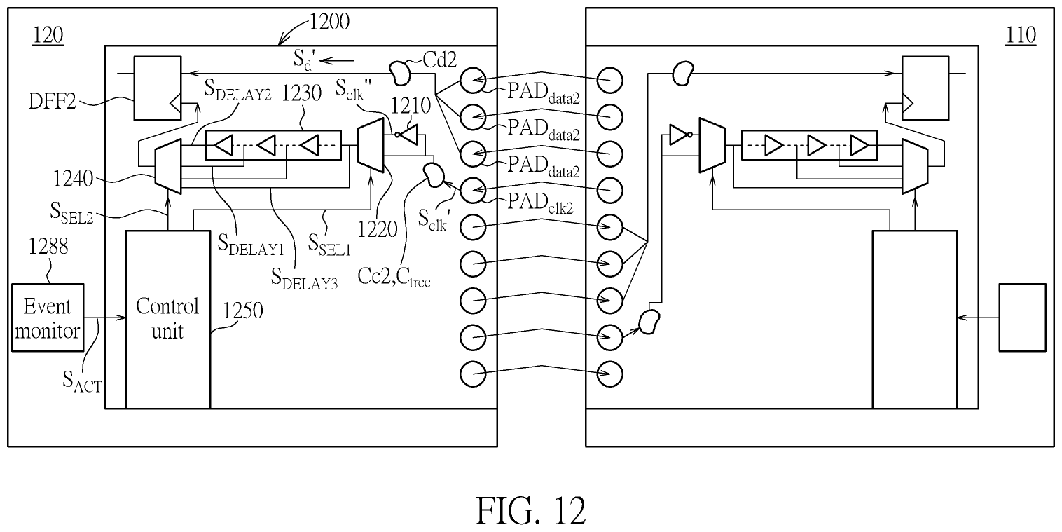

FIG. 1 may show a simplified circuit to describe relationship among signals and an approximate structure. In order to perform the flows shown in FIG. 4 to FIG. 6, the circuit shown in FIG. 12 may be used. The circuit in FIG. 12 may also be a simplified diagram but provides more details than the circuit of FIG. 1. FIG .12 illustrates a circuit 1200 capable of adjusting the clock edge Bs of the clock signal S_{clk}′ according to an embodiment. The circuit 1200 may include an inverter 1210, a first multiplexer 1220, a delay unit 1230, a second multiplexer 1240 and a control unit 1250. The inverter 1210 may be used to invert the clock signal S_{clk}′ to generate an inverted clock signal S_{clk}″ and include an input terminal used to receive the clock signal S_{clk}′, and an output terminal used to output the inverted clock signal S_{clk}″. The first multiplexer 1220 may include a first terminal used to receive the clock signal S_{clk}′, a second terminal coupled to the output terminal of the inverter 1210, a selection terminal used to receive a first selection signal S_{SEL1}, and an output terminal used to output the clock signal S_{clk}′ or the inverted clock signal S_{clk}″ according to the first selection signal S_{SEL1}. The delay unit 1230 may include an input terminal and at least a first output terminal to a third output terminal, where the input terminal may be coupled to the output terminal of the first multiplexer 1220, the first output terminal may be used to output a first delayed clock signal S_{DELAY1}, the second output terminal may be used to output a second delayed clock signal S_{DELAY2}, and a third output terminal may be used to output a third delayed clock signal S_{DELAY3.} The first delayed clock signal S_{DEL1} may be generated by delaying a stored clock signal by a predetermined value X and the stored clock signal is used by a flip-flop DFF2 to correctly receive data. The second delayed clock signal S_{DEL2} may be generated by delaying the first delayed clock signal S_{DEL1} by half of the predetermined value X (i.e. X/2). The third delayed clock signal S_{DEL3} may be generated by delaying the stored clock signal by half of the predetermined value X (i.e. X/2). The second multiplexer 1240 may include a first terminal to a fourth terminal, a selection terminal and an output terminal where the first terminal is coupled to the output terminal of the first multiplexer 1220, the second terminal is coupled to the first output terminal of the delay unit 1230, the third terminal is coupled to the second output terminal of the delay unit 1230, the fourth terminal is coupled to the third output terminal of the delay unit 1230, the selection terminal is used to receive a second selection signal S_{SEL2}, and the output terminal is coupled to a clock terminal of the flip-flop DFF2. The control unit 1250 may include an input terminal used to receive an activation signal S_{ACT}, a first output terminal coupled to the selection terminal of the first multiplexer 1220 and used to output the first selection signal S_{SEL1}, and a second output terminal coupled to the selection terminal of the second multiplexer 1240 and used to output the second selection signal S_{SEL2}.

As shown in FIG. 12, the activation signal S_{ACT} may be provided by the event monitor 1288. The control unit 1250 may perform the steps shown in FIG. 4 to FIG. 6. As shown in FIG. 12, the delay unit may include a plurality of delay buffers coupled in series for providing signals delayed to different degrees. The second selection signal S_{SEL2} may include a plurality of bits so as to select two or more signals. The control unit 1250 may perform the flows of FIG. 4 to FIG. 6. For example, the control unit 1250 may set the selection signals S_{SEL1} and S_{SEL2} for the clock terminal of the flip-flop DFF2 to receive the delayed clock signal S_{DELAY1}. If the flip-flop DFF2 can correctly receive data when receiving the delayed clock signal S_{DELAY1,} the control unit 1250 may set the selection signals S_{SEL1} and S_{SEL2} for the clock terminal of the flip-flop DFF2 to receive the delayed clock signal S_{DELAY2}. If the flip-flop DFF2 fails to correctly receive data when receiving the delayed clock signal S_{DELAY1}, the control unit 1250 may set the selection signals S_{SEL1} and S_{SEL2} for the clock terminal of the flip-flop DFF2 to receive the delayed clock signal S_{DELAY3}. According to embodiments, there may be four scenarios as below.

Scenario 1: In FIG. 12, if the flip-flop DFF2 can correctly sample data when the clock terminal of the flip-flop DFF2 receives any of the first delayed clock signal S_{DELAY1} and the second delayed clock signal S_{DELAY2}, and half of the predetermined value X (i.e. X/2) is the minimum precision value, the control unit 1250 may set the clock edge corresponding to the second delayed clock signal S_{DELAY2} as the time limit.

Scenario 2: In FIG. 12, if the flip-flop DFF2 fails to correctly sample data when the clock terminal of the flip-flop DFF2 receives the first delayed clock signal S_{DELAY1,} but the flip-flop DFF2 can correctly sample data when the clock terminal of the flip-flop DFF2 receives the second delayed clock signal S_{DELAY2,} and half of the predetermined value X (i.e. X/2) is the minimum precision value, the control unit 1250 may set the clock edge corresponding to the third delayed clock signal S_{DELAY3} as the time limit.

Scenario 3: In FIG. 12, if the flip-flop DFF2 fails to correctly sample data when the clock terminal of the flip-flop DFF2 receives any of the first delayed clock signal S_{DELAY1} and the third delayed clock signal S_{DELAY3}, and half of the predetermined value X (i.e. X/2) is the minimum precision value, the control unit 1250 may set the last stored clock edge of the clock signal as the time limit where the clock signal is received by the flip-flop DFF2 for the last correct sampling of data. For example, the last stored clock edge may be at an initial position of a clock edge of a clock signal received by the flip-flop DFF2 before the delayed clock signals S_{DELAY1} and S_{DELAY3} are received by the flip-flop DFF2.

Scenario 4: In FIG. 12, if the flip-flop DFF2 can correctly sample data when the clock terminal of the flip-flop DFF2 receives the first delayed clock signal S_{DELAY1}, but the flip-flop DFF2 fails to correctly sample data when the clock terminal of the flip-flop DFF2 receives the second delayed clock signal S_{DELAY2}, and half of the predetermined value X (i.e. X/2) is the minimum precision value, the control unit 1250 may set the clock edge corresponding to the first delayed clock signal S_{DELAY1} as the time limit.

The principles related to Scenario 1 to Scenario 4 may be as described in FIG. 4 to FIG. 6, so it is not repeated. The mentioned time limit may be the first time limit BR and the second time limit BL described above. The clock edge adjustment value Ev may be calculated according to obtained time limits and used to adjust the clock edge Bs of the clock signal S_{clk}′. In the above example, the delay unit 1230 may provide the three delayed clock signals S_{DELAY1} to S_{DELAY3}. However, more delayed clock signals delayed to different degrees may be provided by increasing the number of the delay buffers in the delay unit 1230.

Regarding the inverter 1210, when the clock signal S_{clk}′ is inverted by the inverter 1210 and delayed by the delay unit 1230, the phase of the clock signal S_{clk}′ may be effectively shifted backward in the second direction DL. For example, as shown in FIG. 8, according to the equation (eq-2), the clock edge adjustment value Ev may be −3T/8. Hence, in the circuit of FIG. 12, the control unit 1250 may set the first selection signal S_{SEL1} and the second selection signal S_{SEL2} for the inverter 1210 to output the inverted the clock signal S_{clk}′. The second multiplexer 1240 may therefore output a signal delayed by 5T/8, so a signal delayed −3T/8 may be generated.

Likewise, regarding the example of FIG.10, in the circuit of FIG.12, the control unit 1250 may set the selection signals S_{SEL1} and S_{SEL2} for the multiplexer 1220 to output the inverted clock signal S_{clk}″. The multiplexer 1220 may output a signal delayed by 7T/8, and a signal delayed by −T/8 may be generated.

As shown in FIG.12, because signals can be transmitted bi-directionally between the transmission terminal 110 and the reception terminal 120, the transmission terminal 110 may also include a circuit similar to the circuit 1200 to adjust and improve the signal received by the clock terminal of the flip-flop DFF1. The operation principle may be like that of the circuit 1200 and not repeatedly described.

In summary, the method and the circuit provided by embodiments may be used to automatically respond to events related to chip parameter changes. The position of the clock edge of the clock signal may be improved. A digital circuit may be used to obtain the improved clock edge position, and it can be avoided to use a complex software algorithm requiring a lot of computation resource. It can also be avoided to use a sensor with higher complexity and lower reliability to monitor process, voltage and/or temperature (PVT) for improving the clock edge position. Hence, both feasibility and reliability of the circuit can be improved, and the problems of the field can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for adjusting a clock edge of a clock signal, comprising:
a transmission terminal sending a first set of transmission packets to a reception terminal;
performing a check operation to check at least whether the first set of transmission packets is correctly received;
obtaining a first time limit and a second time limit according to a result of the check operation;
obtaining a clock edge adjustment value according to the first time limit and the second time limit; and
adjusting the clock edge according to the clock edge adjustment value.

2. The method of claim 1, further comprising:
the reception terminal sending a set of response packets to the transmission terminal;
wherein the check operation is performed to check whether the first set of transmission packets and the set of response packets are correctly received.

3. The method of claim 1, further comprising:
the transmission terminal sending a second set of transmission packets to the reception terminal;
wherein the check operation is performed to check whether the first set of transmission packets and the second set of transmission packets are correctly received, and obtaining the first time limit according to the result of the check operation comprises:
moving the clock edge by a predetermined value in a first direction to a first update position;
sending the first set of transmission packets when the clock edge is at the first update position;
checking whether the first set of transmission packets is correctly received;
moving the clock edge by half of the predetermined value in the first direction from the first update position to a second update position when the first set of transmission packets is correctly received;
the transmission terminal sending the second set of transmission packets to the reception terminal when the clock edge is at the second update position; and
checking whether the second set of transmission packets is correctly received.

4. The method of claim 3 wherein obtaining the first time limit according to the result of the check operation further comprises:
checking whether half of the predetermined value is a minimum precision value; and
setting the second update position as the first time limit when the second set of transmission packets is correctly received and half of the predetermined value is the minimum precision value.

5. The method of claim 3, wherein obtaining the first time limit according to the result of the check operation further comprises:
checking whether the half of the predetermined value is a minimum precision value; and
setting the first update position as the first time limit when the second set of transmission packets fails to be correctly received and half of the predetermined value is the minimum precision value.

6. The method of claim 1, further comprising:
the transmission terminal sending a second set of transmission packets to the reception terminal;
wherein the check operation is performed to check whether the second set of transmission packets is correctly received, and obtaining the first time limit according to the result of the check operation comprises:
moving the clock edge by a predetermined value in a first direction to a first update position from an initial position;
sending the first set of transmission packets when the clock edge is at the first update position;
checking whether the first set of transmission packets is correctly received;
moving the clock edge by half of the predetermined value in a second direction opposite to the first direction from the first update position to a second update position when the first set of transmission packets fails to be correctly received;
the transmission terminal sending the second set of transmission packets to the reception terminal when the clock edge is at the second update position; and
checking whether the second set of transmission packets is correctly received.

7. The method of claim 6, wherein obtaining the first time limit according to the result of the check operation further comprises:
checking whether half of the predetermined value is a minimum precision value; and
setting the initial position of the clock edge as the first time limit when the second set of transmission packets fails to be correctly received and half of the predetermined value is the minimum precision value.

8. The method of claim 6 wherein obtaining the first time limit according to the result of the check operation further comprises:
checking whether half of the predetermined value is a minimum precision value; and
setting the second update position as the first time limit when the second set of transmission packets is correctly received and half of the predetermined value is the minimum precision value.

9. The method of claim 1 further comprising activating an adjustment flow when a predetermined condition is reached.

10. The method of claim 1 wherein the first set of transmission packets comprises a start packer, a data packet and an end packet.

11. A circuit for adjusting a clock edge of a clock signal, comprising:
an inverter configured to invert a clock signal to generate an inverted clock signal and comprising an input terminal configured to receive the clock signal, and an output terminal configured to output the inverted clock signal;
a first multiplexer comprising a first terminal configured to receive the clock signal, a second terminal coupled to the output terminal of the inverter, a selection terminal configured to receive a first selection signal, and an output terminal configured to output the clock signal or the inverted clock signal according to the first selection signal;
a delay unit comprising an input terminal coupled to the output terminal of the first multiplexer, a first output terminal configured to output a first delayed clock signal, a second output terminal configured to output a second delayed clock signal, and a third output terminal configured to output a third delayed clock signal wherein the first delayed clock signal is generated by delaying a stored clock signal by a predetermined value and the stored clock signal is used by a flip-flop to correctly receive data, the second delayed clock signal is generated by delaying the first delayed clock signal by half of the predetermined value, and the third delayed clock signal is generated by delaying the stored clock signal by half of the predetermined value;
a second multiplexer comprising a first terminal coupled to the output terminal of the first multiplexer, a second terminal coupled to the first output terminal of the delay unit, a third terminal coupled to the second output terminal of the delay unit, a fourth terminal coupled to the third output terminal of the delay unit, a selection terminal configured to receive a second selection signal, and an output terminal coupled to a clock terminal of the flip-flop; and
a control unit comprising an input terminal configured to receive an activation signal, a first output terminal coupled to the selection terminal of the first multiplexer and configured to output the first selection signal, and a second output terminal coupled to the selection terminal of the second multiplexer and configured to output the second selection signal.

12. The circuit of claim 11, wherein:
the control unit determines the first selection signal and the second selection signal so that the clock terminal of flip-flop receives the first delayed clock signal;
the control unit determines the first selection signal and the second selection signal so that the clock terminal of flip-flop receives the second delayed clock signal when the flip-flop correctly receives the data; and
the control unit determines a clock edge corresponding to the second delayed clock signal as a time limit when the flip-flop correctly receives the data and half of the predetermined value is a minimum precision value;
wherein the time limit is used to adjust a signal received by the clock terminal of the flip-flop.

13. The circuit of claim 11, wherein:
the control unit determines the first selection signal and the second selection signal so that the clock terminal of flip-flop receives the first delayed clock signal;
the control unit determines the first selection signal and the second selection signal so that the clock terminal of flip-flop receives the third delayed clock signal when the flip-flop fails to correctly receive the data; and
the control unit determines a clock edge corresponding to the third delayed clock signal as a time limit when the flip-flop correctly receives the data and half of the predetermined value is a minimum precision value;
wherein the time limit is used to adjust a signal received by the clock terminal of the flip-flop.

14. The circuit of claim 11, wherein:
the control unit determines the first selection signal and the second selection signal so that the clock terminal of flip-flop receives the first delayed clock signal;
the control unit determines the first selection signal and the second selection signal so that the clock terminal of flip-flop receives the third delayed clock signal when the flip-flop fails to correctly receive the data; and
the control unit determines a clock edge corresponding to the stored clock signal as a time limit when the flip-flop fails to correctly receive the data and half of the predetermined value is a minimum precision value;
wherein the time limit is used to adjust a signal received by the clock terminal of the flip-flop.

15. The circuit of claim 11, wherein:
the control unit determines the first selection signal and the second selection signal so that the clock terminal of flip-flop receives the first delayed clock signal;
the control unit determines the first selection signal and the second selection signal so that the clock terminal of flip-flop receives the second delayed clock signal when the flip-flop correctly receives the data; and
the control unit determines a clock edge corresponding to the first delayed clock signal as a time limit when the flip-flop fails to correctly receive the data and half of the predetermined value is a minimum precision value;
wherein the time limit is used to adjust a signal received by the clock terminal of the flip-flop.
